(19) United States
(12) Patent Application Publication
(10) Pub. No.: US 2020/0219666 A1
(43) Pub. Date: Jul. 9, 2020

(54) POWER STORAGE MODULE

(71) Applicant: Taiyo Yuden Co., Ltd., Tokyo (JP)

(72) Inventor: Shigeki MORINO, Tokyo (JP)

(73) Assignee: Taiyo Yuden Co., Ltd., Tokyo (JP)

(21) Appl. No.: 16/650,322

(22) PCT Filed: Aug. 28, 2018
(86) PCT No.: PCT/JP2018/031682

§ 371 Date: Mar. 24, 2020

(30) Foreign Application Priority Data
Sep. 26, 2017 (JP) 2017-185148

(51) Int. Cl. H01G 11/10; H01G 11/22; H01G 2/06; H01G 9/26; H01M 2/20; H05K 3/30; H05K 1/18; H05K 1/11; H05K 3/34

(52) U.S. Cl. CPC H01G 11/10; H01G 11/22; H01G 2/06; H01G 9/26; H05K 3/34; H05K 3/301; H05K 1/181; H05K 1/11; H01M 2/20

(57) ABSTRACT

A power storage module that allows soldered states of terminals of power storage elements to be easily checked by eyes as a power storage module in which a plurality of power storage elements is electrically connected in series. The plurality of power storage elements is disposed on one surface of a board and the positive electrode terminal and the negative electrode terminal are passed through through-holes provided in the board and soldered to another surface of the board. Among the positive electrode terminals and the negative electrode terminals, leading end portions of a positive electrode terminal that is electrically connected to a negative electrode terminal of another power storage element and a negative electrode terminal that is electrically connected to a positive electrode terminal of another power storage element are bent on a side of the other surface of the board and protrude from solder such that the leading end portions are visible by eyes.

### TECHNICAL FIELD

The present invention relates to a power storage module in which a plurality of power storage elements each including a positive electrode terminal and a negative electrode terminal is connected in series.

### BACKGROUND ART

A power storage element such as an electric double-layer capacitor (EDLC) includes a positive electrode terminal and a negative electrode terminal and its rated voltage is typically approximately 2.5V to 3V. Therefore, if a required voltage cannot be obtained only with the power storage element having such a rated voltage, a plurality of power storage elements connected in series on a printed board and housed in a casing is often used as a power storage module as described in Patent Literature 1.

FIG. 5 shows an example of such a power storage module and is a perspective view of a power storage module including two power storage elements mounted on a printed board. FIG. 6 is a view showing soldered states of power storage elements in the power storage module of FIG. 5 from the side. In the power storage module shown in FIG. 5, a first power storage element 2 and a second power storage element 3 are mounted on one surface of a printed board 4. Positive electrode terminals and the negative electrode terminals of the power storage elements are passed through through-holes provided in the printed board 4 and fixed to the other surface of the printed board 4 with solder 7. The positive electrode terminal and the negative electrode terminal positioned at both ends of the printed board 4 are pulled out through the through-holes of the printed board 4, respectively, and used as external terminals 5 of a power storage module 1.

On the other hand, the positive electrode terminal and the negative electrode terminal of the power storage elements, which are positioned inside the external terminals 5, are electrically connected with metal patterns formed in the printed board 4. At this time, the terminals positioned inside the external terminals 5 are cut into a length to slightly protrude from the printed board 4 such that a distance by which the terminals protrude from the other surface of the printed board 4 can be reduced, and then soldered. The reduction of the length of the terminals makes the height of the soldered portions smaller than the height of the put-on solder 7.

### CITATION LIST

### Patent Literature

Patent Literature 1: Japanese unexamined utility model application publication No. SHO58-15343

### DISCLOSURE OF INVENTION

### Technical Problem

However, since the leading end portions of the terminals are embedded in the solder 7 as shown in FIGS. 5 and 6 when the amount of solder 7 used is increased or the terminals are cut into a shorter length, they are invisible from outside. Therefore, since the soldered states of the terminals cannot be checked by eyes, it is difficult to find a soldering failure. The present invention has been made in view of such circumstances and has an object to provide a power storage module that allows soldered states of terminals of power storage elements to be easily checked by eyes.

### Solution to Problem

The present invention has aspects (1) to (3) as follows. (1) A power storage module in which a plurality of power storage elements respectively including positive electrode terminals and negative electrode terminals is electrically connected in series is characterized in that the plurality of power storage elements is disposed on one surface of a board, the positive electrode terminal and the negative electrode terminal are passed through through-holes provided in the board and soldered to another surface of the board, and among the positive electrode terminals and the negative electrode terminals, leading end portions of a positive electrode terminal that is electrically connected to a negative electrode terminal of another power storage element and a negative electrode terminal that is electrically connected to a positive electrode terminal of another power storage element are bent on a side of the other surface of the board and protrude from solder such that the leading end portions are visible by eyes. (2) In (1), it is characterized in that the leading end portion is bent along the other surface of the board. (3) In (1) or (2), it is characterized in that the leading end portion is bent not to protrude from outer edges of the board in a planar view.

### ADVANTAGEOUS EFFECTS OF INVENTION

In accordance with the present invention, it is possible to provide a power storage module that allows soldered states of terminals of power storage elements to be easily checked by eyes.

### BRIEF DESCRIPTION OF DRAWINGS

FIG. 1 A perspective view of a power storage module according to an embodiment.

FIG. 2 A view showing soldered states of power storage elements.

FIG. 3 A view schematically showing a bent terminal.

FIG. 4 A perspective view of a power storage module according to another embodiment.

FIG. 5 A perspective view of a conventional power storage module.

FIG. 6 A view showing soldered states of power storage elements.

### MODE(S) FOR CARRYING OUT THE INVENTION

Hereinafter, an embodiment of a power storage module according to the present invention will be described with reference to the drawings.

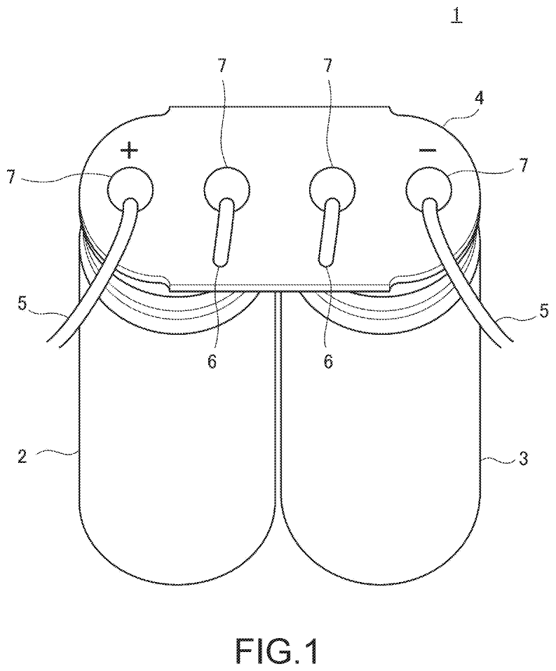

FIG. 1 is a perspective view of a power storage module 1 according to the embodiment. The power storage module 1 according to the embodiment is obtained by integrally mounting a first power storage element 2 and a second power storage element 3 each including a positive electrode terminal and a negative electrode terminal in series on a printed board 4 that is a board. Electric double-layer capacitors (EDLCs) can be used as the first and second power storage elements 2 and 3. For example, two EDLCs having the same rated voltage are used.

The first power storage element 2 and the second power storage element 3 are arranged in line on one surface of the printed board 4. The printed board 4 is provided with through-holes through which the positive electrode terminals and the negative electrode terminals of the first and second power storage elements 2 and 3 are passed. The respective terminals are fixed to the other surface of the printed board 4 with solder 7.

The positive electrode terminal of the first power storage element 2 and the negative electrode terminal of the second power storage element 3 are pulled out through the through-holes of the printed board 4 and used as external terminals 5 of the power storage module 1. Further, the negative electrode terminal of the first power storage element 2 and the positive electrode terminal of the second power storage element 3, which are positioned inside the external terminals 5, are terminals 6 electrically connected with metal patterns of the printed board 4. By electrically connecting the negative electrode terminal of the first power storage element 2 and the positive electrode terminal of the second power storage element 3 to each other, the first power storage element 2 and the second power storage element 3 are connected in series.

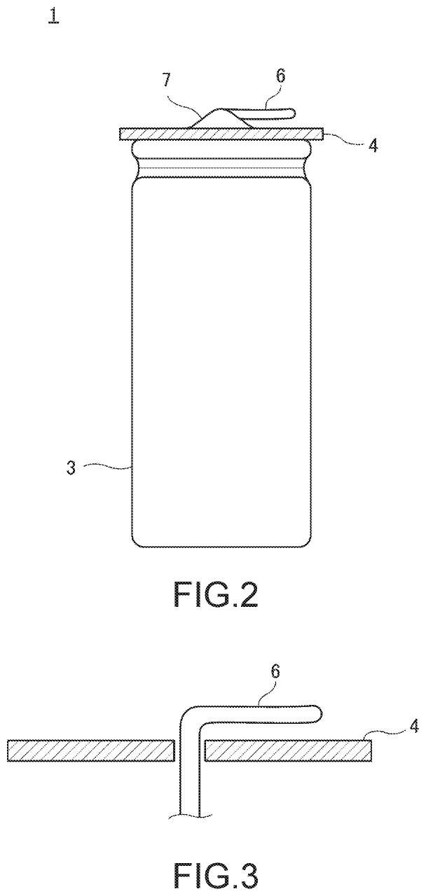

FIG. 2 is a view showing soldered states of power storage elements and shows a soldered portion of the terminal 6 of the second power storage element 3 from the side. FIG. 3 is a view schematically showing a state of the leading end portion of the terminal 6 without the solder 7 at the soldered portion of the terminal 6. As shown in FIGS. 2 and 3, the terminal 6 according to the embodiment protrudes to the other surface of the printed board 4 and the leading end portion of the protruding terminal 6 is bent substantially parallel with the other surface of the printed board 4. Soldering is performed on the portion at which the terminal 6 has been bent. As shown in FIGS. 1 and 2, the leading end portions of the terminals 6 protrude in a direction in which they have been bent from the solder 7 put on the printed board 4. Since the states of the terminals 6 and the solder 7 of the soldered portions are visible from outside, whether or not the soldering has been suitably performed can be easily judged by eyes. Further, if a soldering failure is found, it can also be easily corrected using a soldering iron or the like.

Since the leading end portions of the terminals 6 have been bent along the other surface of the printed board 4, the leading end portions of the terminals 6 protrude along the other surface of the printed board 4 and do not protrude in a thickness direction even in a case where the terminals 6 are so long that the terminals 6 protrude from the solder 7. The height of the soldered portions of the terminals 6 is approximately equal to the height of the solder 7 put on the printed board 4 as in the conventional one. Further, in a planar view, the leading end portions of the terminals 6 have a length such that they fall within a planar-surface range of the printed board 4 without protruding from outer edges of the printed board 4 as viewed in the planar view. Therefore, a small space is required even in the case where the terminals 6 are so long that the terminals 6 protrude from the solder 7. It does not significantly affect downsizing of the power storage module.

Further, since the leading end portion of the terminal 6 is bent before the soldering process, the board 4 is stably sandwiched between the main body of the power storage element 3 and the terminal 6 after bending, which can improve the efficiency for the soldering process. The bending work for the leading end portion of the terminal 6 may be performed after the terminal 6 is passed through the through-hole of the printed board 4.

Alternatively, the power storage element including the terminal 6 whose leading end portion has been bent may be prepared and the bent terminal 6 may be passed through the through-hole of the printed board 4. Note that although FIGS. 1 and 2 each show the state in which the soldered portions of the power storage elements are exposed for the sake of description, the terminals 6, the solder 7, and the like may be covered with insulating material for preventing short-circuit and protecting the soldered portions. Further, the power storage module 1 may be housed in a casing or the like.

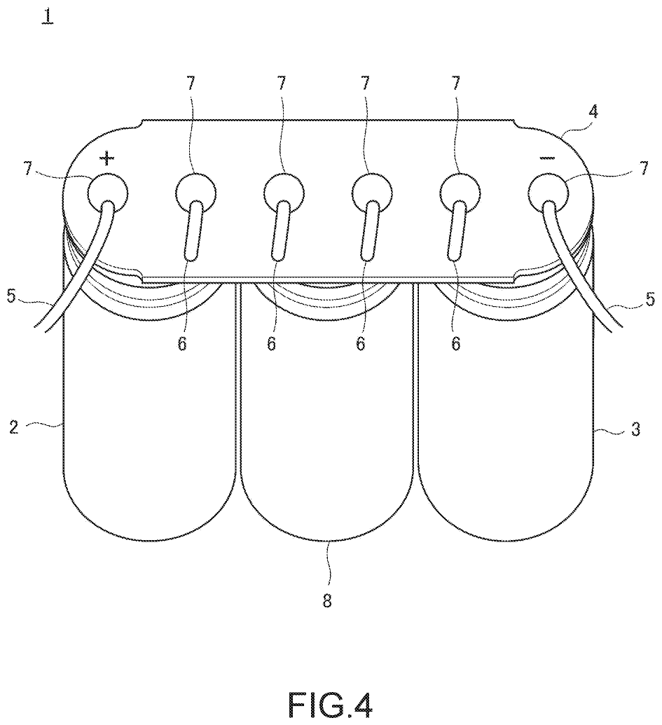

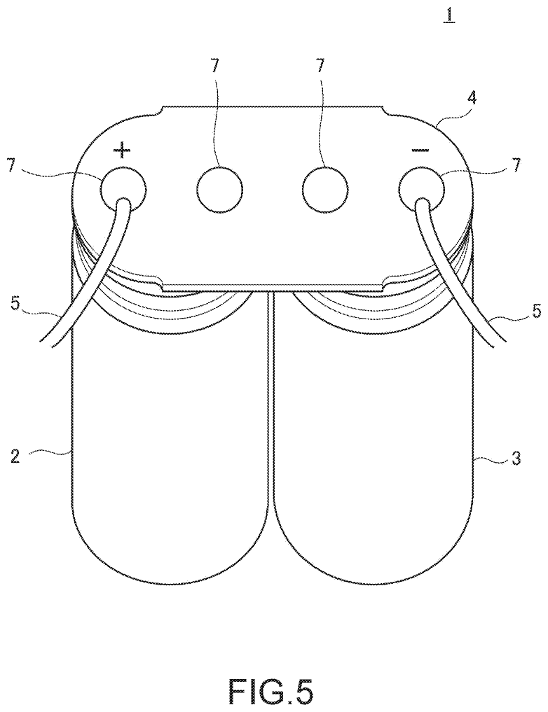

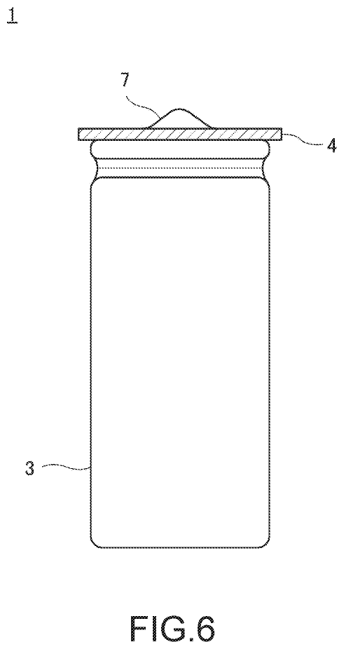

FIG. 4 is a perspective view of a power storage module 1 according to another embodiment of the present invention. In the other embodiment, three power storage elements are integrally mounted in series on a printed board 4. For example, it is a power storage module in which three EDLCs having the same rated voltage are connected in series. In the other embodiment, a positive electrode terminal of a first power storage element 2 and a negative electrode terminal of a second power storage element 3 are pulled out through through-holes of the printed board 4 and used as external terminals 5 of the power storage module 1. A negative electrode terminal of the first power storage element 2, a positive electrode terminal of the second power storage element 3, and a positive electrode terminal and a negative electrode terminal of a third power storage element 8, which are located inside the external terminals 5, are terminals 6 each electrically connected to a positive or negative electrode terminal of other adjacent power storage elements. The first to third power storage elements 2, 3, and 8 are connected in series with metal patterns provided on the printed board 4.

Also in the other embodiment, regarding soldered portions of the terminals 6, leading end portions of the protruding terminals 6 are bent from the other surface of the printed board 4 substantially parallel with the other surface of the printed board 4 as shown in FIGS. 2 and 3 and soldered at the bent portions on the printed board 4. Since the terminals 6 have been bent in the same direction and the leading end portions of the terminals 6 protrude in the direction in which they have been bent from solder 7 put on the printed board 4 such that they are visible by eyes, whether or not the soldering has been suitably performed can be easily judged.

In a case where the power storage element including the terminals 6 bent in advance is prepared as the third power storage element 8 before the terminals 6 are passed through the through-holes of the printed board 4, the bending direction of the terminals 6 may be 2 0 fixed with respect to the positive electrode terminal and the negative electrode terminal, such that the polarities of the terminals 6 of the third power storage element 8 are distinguishable even after the bent terminals 6 are passed through the through-holes of the printed board 4. For example, if the terminals 6 are incorrectly passed with the polarities inverted when the terminals 6 of the third power storage element 8 are attached to the printed board 4 in FIG. 4, the bending direction of the terminals 6 passed through the printed board is opposite by 180 degrees, and thus it can be easily found.

As the number of power storage elements connected in series increases, the number of soldered portions of the terminals 6 increases. With the power storage module according to the present invention, whether or not the soldering has been suitably performed can be judged by eyes. Therefore, the soldering workability can be enhanced and the reliability of the soldered portions can be enhanced.

Although the favorable embodiments of the present invention have been specifically described above, the present invention is not limited those embodiments and various modifications or variants can be made without departing from the gist of the present invention defined in the scope of claims.

### REFERENCE SIGNS LIST

1 power storage module
2 first power storage element
3 second power storage element
4 printed board
5 external terminal
6 terminal
7 solder
8 third power storage element

1. A power storage module in which a plurality of power storage elements respectively including positive electrode terminals and negative electrode terminals is electrically connected in series, wherein:
the plurality of power storage elements is disposed on one surface of a board,
the positive electrode terminal and the negative electrode terminal are passed through through-holes provided in the board and soldered to another surface of the board, and
among the positive electrode terminals and the negative electrode terminals, leading end portions of a positive electrode terminal that is electrically connected to a negative electrode terminal of another power storage element and a negative electrode terminal that is electrically connected to a positive electrode terminal of another power storage element are bent on a side of the other surface of the board and protrude from solder such that the leading end portions are visible by eyes.

2. The power storage module according to claim 1, wherein the leading end portion is bent along the other surface of the board.

3. The power storage module according to claim 1, wherein the leading end portion is bent not to protrude from outer edges of the board in a planar view.

4. The power storage module according to claim 2, wherein the leading end portion is bent not to protrude from outer edges of the board in a planar view.
